(19) United States
(12) Patent Application Publication
(10) Pub. No.: US 2010/0225378 A1
(43) Pub. Date: Sep. 9, 2010

(54) RADIO FREQUENCY SWITCHING CIRCUIT AND SEMICONDUCTOR DEVICE

(75) Inventors: Tadayoshi NAKATSUKA, Hyogo (JP); Shinji YAMAMOTO, Osaka (JP)

Correspondence Address: GREENBLUM & BERNSTEIN, P.L.C., 1950 ROLAND CLARKE PLACE, RESTON, VA, 20191, US

(73) Assignee: PANASONIC CORPORATION, Osaka (JP)

(21) Appl. No.: 12/709,709

(22) Filed: Feb. 22, 2010

(30) Foreign Application Priority Data
Mar. 5, 2009 (JP) 2009-051848
Feb. 4, 2010 (JP) 2010-023608

(51) Int. Cl. H03K 17/687

(52) U.S. Cl. 327/434

(57) ABSTRACT

A radio frequency switching circuit includes: a first switching element; a second switching element; a first biasing resistive element connected to a control terminal of the first switching element; a second biasing resistive element connected to a control terminal of the second switching element; and a control circuit which controls the first switching element and the second switching element according to a control signal being output from a control signal output terminal. C1>C2, and Rb 1<Rb2 are satisfied, where the capacitance of the control terminal of the first switching element is C1, the capacitance of the control terminal of the second switching element is C2, the resistance value of the first biasing resistive element is Rb1, and the resistance value of the second biasing resistive element 204a is Rb2.

### BACKGROUND OF THE INVENTION

(1) Field of the Invention

The present invention relates to a radio frequency switching circuit and a semiconductor device with reduced switching time.

(2) Description of the Related Art

In recent years, with improved performance and high speed of mobile communication apparatuses, next generation communication systems have been proposed which expand transmission capacity in wireless communication. For such a next generation communication system, there is a strong demand for higher band of usable frequency and high speed switching of radio frequency signals. Thus, radio frequency semiconductor switching elements which include compound semiconductor elements are used. However, a conventional radio frequency semiconductor switching element requires a few micro seconds for switching the signal path; and thus, there is a disadvantage whereby it cannot be used in the next generation communication system. To overcome this problem, there is a proposed technique which uses a buffer at an output side of a control circuit (see patent document 1: Japanese Patent Application Publication No. 2008-283277).

Hereinafter, a method for improving switching time disclosed in patent document 1 is described with reference to FIG. 8.

A semiconductor switching circuit shown in FIG. 8 includes a switching circuit 38, and a control circuit 37 which controls the switching circuit 38 based on an externally input signal. The switching circuit 38 includes: a first switching field effect transistor (hereinafter, the field effect transistor is referred to as FET) 9, a second switching FET 10, a third switching FET 11, and a fourth switching FET 12. The control circuit 37 includes: an inverter circuit 28 having an inverter FET 6, a buffer circuit 31 having a first buffer FET 7 and a second buffer FET 8, inverters 29 and 30; and a buffer 32. The gate of each of the FETs of the switching circuit is connected to the associated gate biasing resistances 14, 15, 16, and 17 that have the same resistance value.

In FIG. 8, application of a high control signal to an external control terminal 2 switches the inverter FET 6 and the second buffer FET 8 to an on state, the first buffer FET 7 to an off state, and the gates of the first switching FET 9 and the fourth switching FET 12 to be at ground potential. This causes the first switching FET 9 and the fourth switching FET 12 to be in an off state. Here, since an output of the buffer 32 is a high signal, the second switching FET 10 and the third switching FET 11 are switched to an on state.

Further, application of a low control signal to the external control terminal 2 switches the inverter FET 6 and the buffer FET 8 to an off state, the first buffer FET 7 to an on state, and the first switching FET 9 and the fourth switching FET 12 to an on state. Here, since an output of the buffer 32 is a low signal, the second switching FET 10 and the third switching FET 11 are switched to an off state.

In the case where the switching circuit 38 is operated only with the inverter circuit 28 without using the buffer circuit 31, switching time becomes longer depending on the time constant (Cg×Rd) determined by gate capacitance (Cg) of the first switching FET 9 and load resistance 13 (Rd) of the inverter circuit 28. However, as shown in FIG. 8, addition of the buffer circuit 31 decreases the time constant; and thus, switching time is reduced.

With the above structure, switching speed can be improved.

However, in order to cause the FET that is in an off state to be in an on state for switching the path for radio frequency signals, gate capacitance of the FET needs to be charged. The time required for charging the gate capacitance is determined by the time constant of the gate biasing resistance and gate capacitance.

For a radio frequency switching circuit having a transfer path and a shunt path, the size of the FET arranged on the transfer path is generally about a few times larger than the size of the FET arranged on the shunt path. More specifically, the gate width of the transfer path FET is larger than that of the shunt path FET. On the other hand, the gate width of the shunt path FET is smaller than that of the transfer path FET. Therefore, the time constant while the transfer path is brought to be in an on state is a few times greater than the time constant while the shunt path is brought to be in an on state. On the other hand, the time constant while the shunt path is brought to be in an on state is smaller than the time constant while the transfer path is brought to be in an on state.

As shown in FIG. 9A, with the conventional configuration of FIG. 8, the gates of the first switching FET 9 that is a transfer path FET and the fourth switching FET 12 that is a shunt path FET are simultaneously brought to be in a high state. However, as described above, the gate width of the fourth switching FET 12 is smaller than the gate width of the first switching FET 9; and thus, the fourth switching FET 12 has a smaller time constant. Therefore, time required for causing the fourth switching FET 12 to be in an on state is shorter than time required for causing the first switching FET 9 to be in an on state.

As a result, common potential at point A in the switching circuit 38 increases more rapidly in the case where both of the first switching FET 9 and the fourth switching FET 12 are switched to an on state than the case where only the first switching FET 9 is switched to an on state.

The increase of the common potential prevents gate-to-source voltage or gate-to-drain voltage of the first switching FET 9 from increasing, and delays time at which the first switching FET 9 is switched to an on state. This results in delaying switching time of the radio frequency signal which passes through the first switching FET 9.

Here, when a radio frequency signal is input from an RF signal terminal 4 and transmitted to an RF signal terminal 3, time period during which the output of the radio frequency signal reaches 90% after a control signal is input is defined as switching time. Accordingly, as shown in FIG. 9B, switching time Tr1 in the case where the first switching FET 9 and the fourth switching FET 12 are both switched to an on state is longer than switching time Tr0 in the case where only the first switching FET 9 is switched to an on state.

As described, with the conventional structure, the time constants of FETs which are simultaneously switched to an on state are different, which causes a problem that the switching time of the radio frequency signal is delayed.

Further, with the conventional configuration, when a high-power signal is input, the radio frequency signal is coupled to the control signal lines 40 to 43 at radio frequency, and thereby the radio frequency signal is input to the control circuit through the output terminal of the control circuit. As a result, a problem occurs that the first buffer FET 7 and the second buffer FET 8 do not work correctly, making the output of the control circuit unstable, and resulting in malfunctioning the switching circuit.

### SUMMARY OF THE INVENTION

The present invention is to solve the conventional problems, and has an objective to provide a radio frequency switching circuit and a semiconductor device which reduce switching time and also allow stable operation of the switching circuit.

In order to solve the conventional problems, a first radio frequency switching circuit according to an aspect of the present invention includes: a first switching element which includes a control terminal and switches between on and off states according to a control signal being input to the control terminal; a second switching element which includes a control terminal and switches between on and off states according to the control signal being input to the control terminal; a first biasing resistive element which includes one terminal connected to the control terminal of the first switching element; a second biasing resistive element which includes one terminal connected to the control terminal of the second switching element; and a control circuit which includes a control signal output terminal connected to the other terminal of the first biasing resistive element and the other terminal of the second biasing resistive element, and controls the first switching element and the second switching element according to the control signal being output from the control signal output terminal. In the first radio frequency switching circuit, C1>C2 and Rb1<Rb2 are satisfied (i) where a capacitance of the control terminal of the first switching element is C1, and a capacitance of the control terminal of the second switching element is C2, and (ii) where a resistance value of the first biasing resistive element is Rb1, and a resistance value of the second biasing resistive element is Rb2.

Further, it is preferable in the first radio frequency switching circuit according to an aspect of the present invention that each of the first switching element and the second switching element is formed of a field effect transistor, and the control terminal of each of the first switching element and the second switching element is a gate terminal, and W1>W2 is satisfied, where a gate width of the field effect transistor forming the first switching element is W1, and a gate width of the field effect transistor forming the second switching element is W2.

Further, it is preferable in the first radio frequency switching circuit according to an aspect of the present invention that both of the first switching element and the second switching element are switched to an on state or an off state according to the control signal.

Further, it is preferable in the first radio frequency switching circuit according to an aspect of the present invention that C1 is a capacitance between the control terminal of the first switching element and ground, and C2 is a capacitance between the control terminal of the second switching element and ground.

Further, a second radio frequency switching circuit according to an aspect of the present invention includes: a third switching element which includes a control terminal and switches between on and off states according to the control signal being input to the control terminal; a fourth switching element which includes a control terminal and switches between on and off states according to the control signal being input to the control terminal; a third biasing resistive element which includes one terminal connected to the control terminal of the third switching element; and a fourth biasing resistive element which includes one terminal connected to the control terminal of the fourth switching element. In the second radio frequency switching circuit, the other terminal of the third biasing resistive element and the other terminal of the fourth biasing resistive element are connected to the control signal output terminal, the third switching element is connected in series with the first switching element, and the first switching element and the third switching element form a first switch unit, the fourth switching element is connected in series with the second switching element, and the second switching element and the fourth switching element form a second switch unit, and Ct1>Ct2 and Rp1<Rp2 are satisfied, (i) where a sum of the capacitance of the control terminal of the first switching element and a capacitance of the control terminal of the third switching element is Ct1, the first switching element and the third switching element forming the first switch unit, and a sum of the capacitance of the control terminal of the second switching element and a capacitance of the control terminal of the fourth switching element is Ct2, the second switching element and the fourth switching element forming the second switch unit, and (ii) where a parallel resistance value of the first biasing resistive element and the third biasing resistive element that are respectively connected to the first switching element and the third switching element is Rp1, the first switching element and the third switching element forming the first switch unit, and a parallel resistance value of the second biasing resistive element and the fourth biasing resistive element that are respectively connected to the second switching element and the fourth switching element is Rp2, the second switching element and the fourth switching element forming the second switch unit.

Further, it is preferable in the second radio frequency switching circuit according to an aspect of the present invention that each of the first switching element, the second switching element, the third switching element, and the fourth switching element is formed of a field effect transistor, and the control terminal of each of the first switching element, the second switching element, the third switching element, and the fourth switching element is a gate terminal, and Wt1>Wt2 is satisfied where a sum of a gate width of the field effect transistor of the first switching element and a gate width of the field effect transistor of the third switching element is Wt1, the first switching element and the third switching element forming the first switch unit, and where a sum of a gate width of the field effect transistor of the second switching element and a gate width of the field effect transistor of the fourth switching element is Wt2, the second switching element and the fourth switching element forming the second switch unit.

Further, it is preferable in the second radio frequency switching circuit according to an aspect of the present invention that all of the first switching element, the second switching element, the third switching element, and the fourth switching element are switched to an on state or an off state according to the control signal.

Further, it is preferable in the second radio frequency switching circuit according to an aspect of the present invention that Ct1 is calculated based on a capacitance between the control terminal of the first switching element and ground and a capacitance between the control terminal of the third switching element and ground, and Ct2 is calculated based on a capacitance between the control terminal of the second switching element and ground and a capacitance between the control terminal of the fourth switching element and ground.

Further, a third radio frequency switching circuit according to an aspect of the present invention includes: a first switching element which includes a control terminal and switches between on and off states according to a control signal being input to the control terminal; a second switching element which includes a control terminal and switches between on and off states according to the control signal being input to the control terminal; a first biasing resistive element which includes one terminal connected to the control terminal of the first switching element; a second biasing resistive element which includes one terminal connected to the control terminal of the second switching element; a radio frequency attenuating element connected to at least one of the other terminal of the first biasing resistive element and the other terminal of the second biasing resistive element; and a control circuit which includes a control signal output terminal connected to an input terminal of the radio frequency attenuating element and controls on and off states of the first switching element and the second switching element according to the control signal being output from the control signal output terminal.

Further, it is preferable in the third radio frequency switching circuit according to an aspect of the present invention that the radio frequency attenuating element is formed of at least one resistive element.

Further, it is preferable that the third radio frequency switching circuit according to an aspect of the present invention further includes a capacitor which includes one terminal connected to an output terminal of the at least one resistive element forming the radio frequency attenuating element and the other terminal being grounded.

Further, it is preferable that the third radio frequency switching circuit according to an aspect of the present invention further includes a capacitor which includes one terminal connected to an input terminal of the at least one resistive element forming the radio frequency attenuating element and the other terminal being grounded.

Further, it is preferable in the third radio frequency switching circuit according to an aspect of the present invention that the at least one resistive element forming the radio frequency attenuating element includes a plurality of resistive elements, the plurality of resistive elements include: a first resistive element connected to the other terminal of the first biasing resistive element; and a second resistive element connected to the other terminal of the second biasing resistive element, and a resistance value of the first resistive element is different from a resistance value of the second resistive element.

Further, it is preferable in the third radio frequency switching circuit according to an aspect of the present invention that τ1>τ2 and Rd1<Rd2 are satisfied, (i) where a time constant of a load connected to an output terminal of the first resistive element is τ1 and a time constant of a load connected to an output terminal of the second resistive element is τ2, and (ii) where a resistance value of the first resistive element is Rd1 and a resistance value of the second resistive element is Rd2.

Further, it is preferable in the third radio frequency switching circuit according to an aspect of the present invention that the at least one resistive element forming the radio frequency attenuating element includes a plurality of resistive elements, the plurality of resistive elements include: a first resistive element connected to the other terminal of the first biasing resistive element; and a second resistive element connected to the other terminal of the second biasing resistive element, each of the first switching element and the second switching element is formed of a field effect transistor, the control terminal of each of the first switching element and the second switching element is a gate terminal, and W1>W2, and Rb1+Rd1<Rb2+Rd2 are satisfied, (i) where a gate width of the field effect transistor forming the first switching element is W1, and a gate width of the field effect transistor forming the second switching element is W2, (ii) where a resistance value of the first biasing resistive element is Rb1, and a resistance value of the second biasing resistive element is Rb2, and (iii) where a resistance value of the first resistive element is Rd1, and a resistance value of the second resistive element is Rd2.

Further, it is preferable that the third radio frequency switching circuit according to an aspect of the present invention includes: a third switching element which includes a control terminal and switches between on and off states according to the control signal being input to the control terminal; a fourth switching element which includes a control terminal and switches between on and off states according to the control signal being input to the control terminal; a third biasing resistive element which includes one terminal connected to the control terminal of the third switching element; and a fourth biasing resistive element which includes one terminal connected to the control terminal of the fourth switching element. It is preferable in the third radio frequency switching circuit that the other terminal of the third biasing resistive element and the other terminal of the fourth biasing resistive element are connected to the control signal output terminal, the third switching element is connected in series with the first switching element, and the first switching element and the third switching element form a first switch unit, the fourth switching element is connected in series with the second switching element, and the second switching element and the fourth switching element form a second switch unit, each of the first switching element, the second switching element, the third switching element, and the fourth switching element is formed of a field effect transistor, and the control terminal of each of the first switching element, the second switching element, the third switching element, and the fourth switching element is a gate terminal, the at least one resistive element forming the radio frequency attenuating element includes a plurality of resistive elements; the plurality of resistive elements include: a first resistive element connected to the other terminal of the first biasing resistive element; and a second resistive element connected to the other terminal of the second biasing resistive element, and Wt1>Wt2, and Rp1+Rd1<Rp2+Rd2 are satisfied, (i) where a sum of a gate width of the field effect transistor of the first switching element and a gate width of the field effect transistor of the third switching element is Wt1, the first switching element and the third switching element forming the first switch unit, and a sum of a gate width of the field effect transistor of the second switching element and a gate width of the field effect transistor of the fourth switching element is Wt2, the second switching element and the fourth switching element forming the second switch unit, (ii) where a parallel resistance value of the first biasing resistive element and the third biasing resistive element that are respectively connected to the first switching element and the third switching element is Rp1, the first switching element and the third switching element forming the first switch unit, and a parallel resistance value of the second biasing resistive element and the fourth biasing resistive element that are respectively connected to the second switching element and the fourth switching element is Rp2, the second switching element and the fourth switching element forming the second switch unit, and (iii) where a resistance value of the first resistive element is Rd1 and a resistance value of the second resistive element is Rd2.

Further, a fourth radio frequency switching circuit according to an aspect of the present invention includes: a switching element unit including: at least one transmission terminal; at least one reception terminal; at least one antenna terminal; a transmission path switching element formed of at least one field effect transistor and positioned between the at least one transmission terminal and the at least one antenna terminal; a reception path switching element formed of at least one field effect transistor and positioned between the at least one reception terminal and the at least one antenna terminal; and a shunt path switching element formed of at least one field effect transistor and positioned between the at least one transmission terminal and ground, between the at least one reception terminal and the ground, or between the at least one antenna terminal and the ground, a first biasing resistive element which includes one terminal connected to a control terminal of the transmission path switching element; a second biasing resistive element which includes one terminal connected to a control terminal of the shunt path switching element; a third biasing resistive element which includes one terminal connected to a control terminal of the reception path switching element; a first resistive element connected to the other terminal of the first biasing resistive element; a second resistive element connected to the other terminal of the second biasing resistive element; a third resistive element connected to the other terminal of the third biasing resistive element; and a control circuit which includes a control signal output terminal, and switches on and off states of the transmission path switching element, the reception path switching element, and the shunt path switching element according to a control signal being output from the control signal output terminal. In the fourth radio frequency switching circuit, Rp (TX)+Rd (TX)<Rp (RX)+Rd (RX), or Rp (TX)+Rd (TX)<Rp (SNT)+Rd (SNT) is satisfied, (i) where a parallel resistance value of the first biasing resistive element is Rp (TX), a parallel resistance value of the second biasing resistive element is Rp (SNT), and a parallel resistance value of the third biasing resistive element is Rp (RX), and (ii) where a resistance value of the first resistive element is Rd (TX), a resistance value of the second resistive element is Rd (SNT), and a resistance value of the third resistive element is Rd (RX).

Further, it is preferable in the first to fourth radio frequency switching circuits according to an aspect of the present invention that the control circuit further includes a capacitor, the capacitor having one terminal connected to the control signal output terminal and the other terminal being grounded.

Further, a first semiconductor device according to an aspect of the present invention is a semiconductor device which includes a semiconductor substrate on which the first radio frequency switching circuit according to an aspect of the present invention is integrated.

Further, a second semiconductor device according to an aspect of the present invention is a semiconductor device which includes a semiconductor substrate on which the third radio frequency switching circuit according to an aspect of the present invention is integrated.

With the radio frequency switching circuit and the semiconductor device according to an aspect of the present invention, switching speed can be improved, and stable operation of the control circuit can also be obtained.

### FURTHER INFORMATION ABOUT TECHNICAL BACKGROUND TO THIS APPLICATION

The disclosures of Japanese Patent Application No. 2009-051848 filed on Mar. 5, 2009 and Japanese Patent Application No. 2010-023608 filed on Feb. 4, 2010 including specification, drawings and claims are incorporated herein by reference in their entirety.

### BRIEF DESCRIPTION OF THE DRAWINGS

These and other objectives, advantages and features of the invention will become apparent from the following description thereof taken in conjunction with the accompanying drawings that illustrate a specific embodiment of the invention. In the Drawings:

FIG. 1 is a diagram showing an equivalent circuit of a radio frequency switching circuit according to a first embodiment of the present invention;

FIG. 2A is a diagram showing changes in potential at point B in the radio frequency switching circuit according to the first embodiment of the present invention;

FIG. 2B is a diagram showing comparison of switching time of the radio frequency switching circuit according to the first embodiment of the present invention;

FIG. 3 is a diagram showing an equivalent circuit of a radio frequency switching circuit according to a second embodiment of the present invention;

FIG. 4 is a diagram showing an equivalent circuit of a radio frequency switching circuit according to a third embodiment of the present invention;

FIG. 5 is a diagram showing an equivalent circuit of a radio frequency switching circuit according to a fourth embodiment of the present invention;

FIG. 6 is a diagram showing an equivalent circuit of a radio frequency switching circuit according to a fifth embodiment of the present invention;

FIG. 7 is a diagram showing an equivalent circuit of a radio frequency switching circuit according to a sixth embodiment of the present invention;

FIG. 8 is a diagram showing an equivalent circuit of a conventional radio frequency switching circuit;

FIG. 9A is a diagram showing changes in potential at point A in the conventional radio frequency switching circuit; and

FIG. 9B is a diagram showing comparison of switching time of the conventional radio frequency switching circuit.

### DESCRIPTION OF THE PREFERRED EMBODIMENT(S)

Hereinafter, embodiments of the present invention are described in detail with reference to the drawings.

### First Embodiment

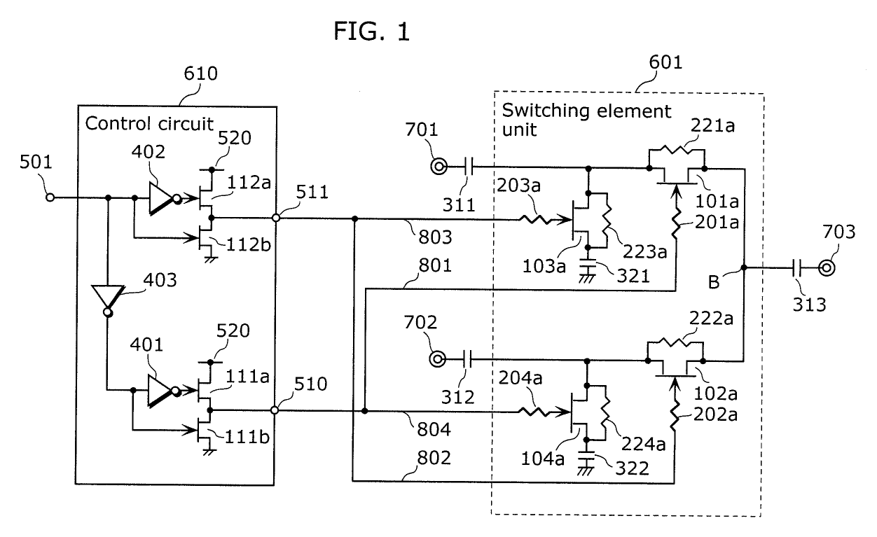

First, a radio frequency switching circuit according to a first embodiment of the present invention is described with reference to FIG. 1. FIG. 1 is a diagram showing an equivalent circuit of the radio frequency switching circuit according to the first embodiment of the present invention, and is a switching circuit referred to as a single pole double throw (SPDT) which switches between two radio frequency signal paths.

As shown in FIG. 1, the radio frequency switching circuit according to the first embodiment of the present invention includes: a switching element unit 601 having switching elements; and a control circuit 610 which controls these switching elements.

The switching element unit 601 includes: a transmission FET 101a that is a FET for transmission path; a reception FET 102a that is a FET for reception path; a shunt FET 103a and a shunt FET 104a that are FETs for shunt paths; biasing resistive elements 201a, 202a, 203a and 204a; and resistive elements 221a, 222a, 223a and 224a. The switching element unit 601 has a function to switch the path between a transmission terminal 701 that is a radio frequency signal terminal and an antenna terminal 703 that is a radio frequency signal terminal, or the path between a reception terminal 702 that is a radio frequency signal terminal and the antenna terminal 703. Each FET has a gate terminal that is a control terminal, a drain terminal that is an input terminal, and a source terminal that is an output terminal. Current flowing between the input terminal and the output terminal is controlled by a control signal being input to the gate terminal, so that each FET is switched between on and off states.

The transmission FET 101a of the switching element unit 601 is positioned between the transmission terminal 701 and the antenna terminal 703. The input terminal of the transmission FET 101a is connected to the transmission terminal 701 via a DC cut capacitor 311, and the output terminal of the transmission FET 101a is connected to the antenna terminal 703 via a DC cut capacitor 313.

The reception FET 102a is positioned between the reception terminal 702 and the antenna terminal 703. The input terminal of the reception FET 102a is connected to the reception terminal 702 via a DC cut capacitor 312, and the output terminal of the reception FET 102a is connected to the antenna terminal 703 via the DC cut capacitor 313.

The shunt FET 103a is positioned between the transmission terminal 701 and ground potential. The input terminal of the shunt FET 103a is connected to the transmission terminal 701 via the DC cut capacitor 311, and the output terminal of the shunt FET 103a is grounded via the DC cut capacitor 321 by, for example, being connected to a ground electrode.

The shunt FET 104a is positioned between the reception terminal 702 and the ground potential. The input terminal of the shunt FET 104a is connected to the reception terminal 702 via the DC cut capacitor 312, and the output terminal of the shunt FET 104a is grounded via the DC cut capacitor 322 by, for example, being connected to the ground electrode.

Further, the gate terminal of the transmission FET 101a is connected to a first terminal (one of the terminals) of the biasing resistive element 201a, and the gate terminal of the shunt FET 104a is connected to a first terminal (one of the terminals) of the biasing resistive element 204a. A second terminal (the other terminal) of the biasing resistive elements 201a is connected to a first control signal output terminal 510 of the control circuit 610 via the control signal line 801, and a second terminal (the other terminal) of the biasing resistive element 204a is connected to the first control signal output terminal 510 via the control signal line 804.

Further, the gate terminal of the reception FET 102a is connected to a first terminal (one of the terminals) of the biasing resistive element 202a, and the gate terminal of the shunt FET 103a is connected to a first terminal (one of the terminals) of the biasing resistive element 203a. A second terminal (the other terminal) of the biasing resistive element 202a is connected to a second control signal output terminal 511 of the control circuit 610 via a control signal line 802, and a second terminal (the other terminal) of the biasing resistive element 203a is connected to the second control signal output terminal 511 via the control signal line 803.

Note that the drain-to-source voltage of each of the FET 101a to 104a is determined by leak current that flows through the FET when the FET is switched to an off state from an on state. The resistive elements 221a to 224a that are respectively connected in parallel between the drain and the source of the associated FET 101a to 104a cause the determined voltage to be common in terminal voltage among all FETs.

In the radio frequency switching circuit configured as above, for example, in order to connect the transmission terminal 701 and the antenna terminal 703, the transmission FET 101a is switched to an on state and the shunt FET 103a is switched to an off state. At this time, in order to ensure isolation between the transmission terminal 701 and the reception terminal 702, it is preferable that the reception FET 102a is switched to an off state and the shunt FET 104a is switched to an on state.

The control circuit 610 includes inverters 401, 402 and 403 and buffer FETs 111a, 111b, 112a, and 112b, and has a function to control each FET forming the switching element unit 601. The control circuit 610 is driven by power supply voltage Vdd supplied from each power supply terminal 520 connected to the buffer FETs 111a and 112a. The control circuit 610 outputs, through the first control signal output terminal 510 and the second control signal output terminal 511, an output control signal according to an input control signal being input from the control signal input terminal 501. According to the voltage of the output control signal from the first control output terminal 510 and the second control signal output terminal 511, each FET of the switching element unit 601 is switched between on and off states.

In the radio frequency switching circuit configured as above, both of the transmission FET 101a and the shunt FET 104a are switched to an on state or an off state by the control signal being output from the first control signal output terminal 510 according to the input signal to the control circuit 610. More specifically, the transmission FET 101a and the shunt FET 104a are commonly either in an on state or an off state. Similarly, both of the transmission FET 102a and the shunt FET 103a are switched to an on state or an off state by the control signal being output from the second control signal output terminal 511 according to the input signal to the control circuit 610. More specifically, the reception FET 102a and the shunt FET 103a are commonly either in an on state or an off state.

Here, the gate width of each FET of the switching element unit 601 is optimized according to the electric power that passes through and radio frequency characteristic. For the radio frequency switching circuit according to the first embodiment of the present invention, it is set such that the gate width W1a of the transmission FET 101a is 3000 μM, the gate width W2a of the reception FET 102a is 1000 μM, and the gate widths W3a and W4a of the shunt FETs 103a and 104a are 600 μm. Therefore, where the gate capacitances (pF) of the transmission FET 101a, the reception FET 102a, the shunt FETs 103a and 104a are respectively C1a, C2a, C3a, and C4a, the magnitude relationship of C1a to C4a is C1a>C2a>C3a=C4a.

Further, it is set such that the resistance values of the biasing resistive elements 201a and 202a respectively connected to the gate terminals of the transmission FET 101a and the reception FET 102a are 50 kΩ, and the resistance values of the biasing resistive elements 203a and 204a respectively connected to the gate terminals of the shunt FET 103a and 104a are 250 kΩ. Accordingly, where the resistance values (Ω) of the biasing resistive elements 201a, 202a, 203a, and 204a are respectively Rb1a, Rb2a, Rb3a, and Rb4a, the magnitude relationship of the Rb1a to Rb4a is Rb1a=Rb2a<Rb3a=Rb4a.

The operation of the radio frequency switching circuit according to the first embodiment of the present invention configured as above is hereinafter described.

Firstly, where the control signal input from the control signal input terminal 501 is a low signal, the control circuit 610 outputs 0V from the first control signal output terminal 510, and outputs Vdd that is a power supply voltage from the second control signal output terminal 511. This causes the transmission FET 101a and the shunt FET 104a to be in an off state, and the reception FET 102a and the shunt FET 103a to be in an on state.

Next, when a logic signal input from the control signal input terminal 501 is made to be a high signal, the output from the first control signal output terminal 510 changes from 0V to Vdd, and the output from the second control signal output terminal 511 changes from Vdd to 0V. This changes the transmission FET 101a and the shunt FET 104a that are in an off state to be in an on state, and the reception FET 102a and the shunt FET 103a that are in an on state to be in an off state.

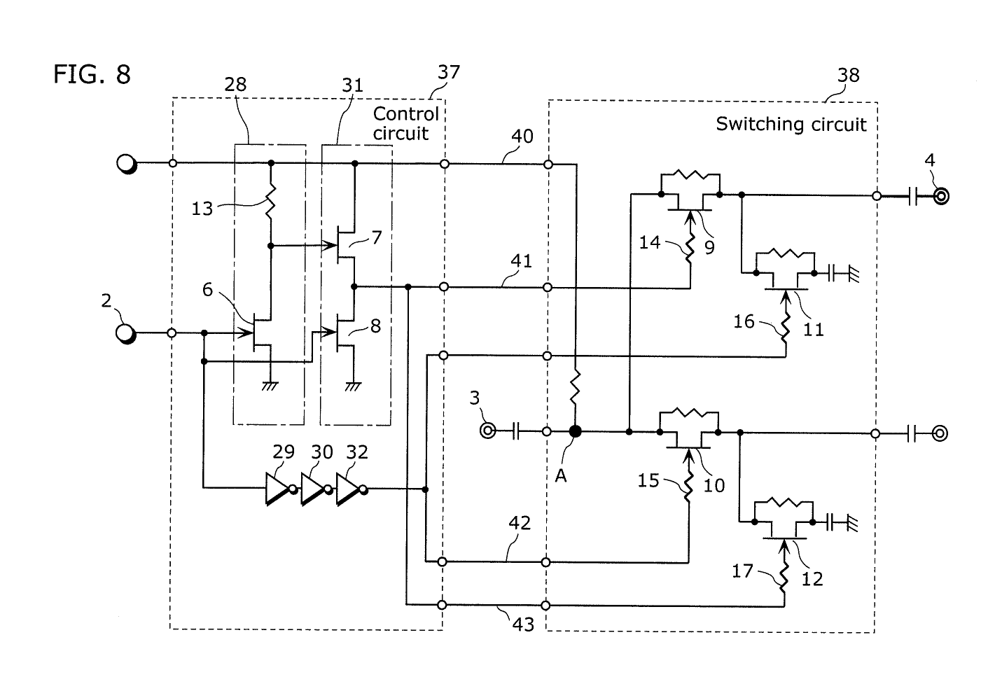

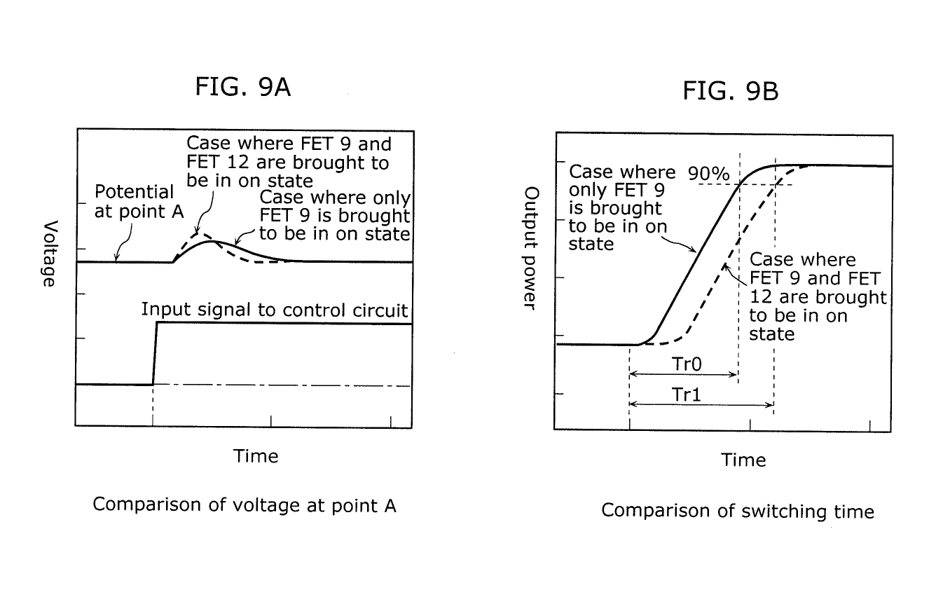

In the configuration of the conventional switching circuit shown in FIG. 8, it is set such that the resistance values of the gate biasing resistances 14 to 17 connected to the gate terminals of the associated FET in the switching circuit 38 are the same. On the other hand, in the radio frequency switching circuit according to the first embodiment of the present invention, as described above, it is set such that the resistance values Rb1a and Rb2a of the biasing resistive elements 201a and 202a are 50 kΩ, and the resistance values Rb3a and Rb4a of the biasing resistive elements 203a and 204a are 100 kΩ. Further, as described above, the gate capacitances C1a to C4a of the transmission FET 101a, the reception FET 102a, the shunt FETs 103a and 104a are C1a>C2a>C3a=C4a.

Here, for example, focusing on only the relationship between the transmission FET 101a and the shunt FET 104a that are switched between on and off states according to the control signal being output from the first control signal output terminal 510, the following relationship is satisfied.

Here, C1>C2, W1>W2, and Rb1<Rb4 are satisfied where the transmission FET 101a is a first switching element, the shunt FET 104a is a second switching element, the biasing resistive element 201a connected to the transmission FET 101a is a first biasing resistive element, the biasing resistive element 204a connected to the shunt FET 104a is a second biasing resistive element, the gate width W1a and the gate capacitance C1a of the transmission FET 101a that is the first switching element are respectively W1 and C1, the gate width W4a and the gate capacitance C1a of the shunt FET 104a that is the second switching element are respectively W2 and C2, the resistance value Rb1a of the biasing resistive element 201a connected to the transmission FET 101a that is the first switching element is Rb1, and the resistance value Rb4a of the biasing resistive element 204a connected to the shunt FET 104a that is the second switching element is Rb2.

Accordingly, in the present embodiment, the time constant determined by the gate capacitance C4 of the shunt FET 104a and the resistance value Rb4a of the biasing resistive element 204a becomes twice of the time constant determined by the gate capacitance C1a of the shunt FET 101a and the resistance value Rb1a of the biasing resistive element 201a. Accordingly, time at which the shunt FET 104a is switched to be an on state can be delayed and the increase of the drain-to-source potential of the transmission FET 101a can be delayed.

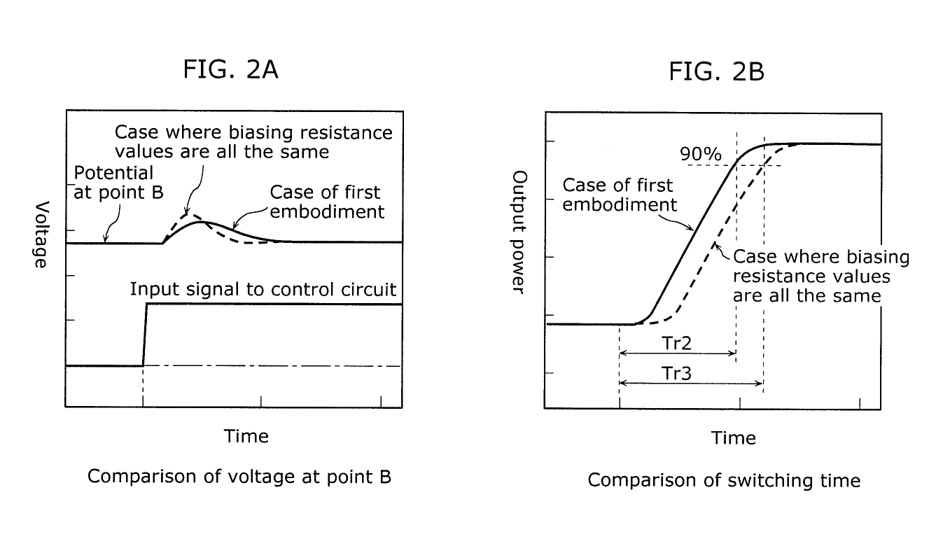

As a result, as shown in FIG. 2A, time at which the potential at point B that is a common potential of the switching element unit 601 increases can be delayed, and the absolute value of the voltage variation can also be decreased. Thus, the increase of the gate-to-source voltage or the gate-to-drain voltage of the transmission FET 101a is not prevented, which allows reduction of time period required for switching the transmission FET 101a to an on state.

Here, in the case where a radio frequency signal is input from the transmission terminal 701 and transmitted to the antenna terminal 703, time period during which the output of the radio frequency signal reaches 90% after a control signal is input is defined as switching time. Accordingly, as shown in FIG. 2B, switching time Tr2 in the radio frequency switching circuit according to the first embodiment of the present invention where the resistance values Rb1a and Rb2a of the biasing resistive elements 201a and 202a are 50 kΩ and the resistance values Rb3a and Rb4a of the biasing resistive elements 203a and 204a are 100 kΩ can be reduced compared to the switching time Tr3 in the conventional switching circuit where the resistance values of the biasing resistive elements 201a to 204a are all the same.

Note that it is similar in the reception FET 102a and the shunt FET 103a which are switched between on and off states according to the control signal being output from the second control signal output terminal 511. More specifically, the gate capacitance C2a of the reception FET 102a and the gate capacitance C3a of the shunt FET 103a have a relationship of C2a>C3a, and the resistance value Rb2a of the biasing resistive element 202a connected to the reception FET 102a and the resistance value Rb3a of the biasing resistive element 203a connected to the shunt FET 103a have a relationship of Rb2a<Rb3a. Thus, time at which the shunt FET 103a is switched to be on state can be delayed, and the increase of the drain-to-source potential of the reception FET 102a can be delayed.

As a result, time at which the potential at point B that is a common potential of the switching element unit 601 increases can be delayed, and the absolute value of the voltage variation can also be decreased. Thus, the increase of the gate-to-source voltage or the gate to drain voltage of the transmission FET 101a is not prevented, which allows reduction of time period required for switching the transmission FET 101a to an on state.

As described, in the first embodiment, of the two FETs that are simultaneously switched to an on state, switching time can be reduced for a control signal path which has a relatively larger gate width of the FET, that is, a control signal path which has a relatively larger gate capacitance by relatively decreasing the biasing resistance value of the biasing resistive element connected to the gate terminal of the FET, compared to the case where a same biasing resistance value is used for the biasing resistive elements.

In the present embodiment, the transmission FET 101a and the reception FET 102b, each of which is a transfer path FET, have gate widths larger than those of the shunt FETs 103a and 104a each of which is a shunt path FET. Therefore, the resistance values of the biasing resistive elements connected to the transmission FET 101a and the reception FET 102a are set to be smaller than the resistance values of the biasing resistive elements connected to the shunt FETs 103a and 104a. This allows reduction of switching time.

Note that in the first embodiment, two paths each of which includes two FETs have been mainly described; however, the present invention can also be applied to the case where two or more paths are used. In this case, switching time can be reduced by, among the FETs on plural paths that are simultaneously switched to an on state, increasing the biasing resistance value of the biasing resistive element connected to the gate terminal of the FET which has a relatively smaller gate width.

### Second Embodiment

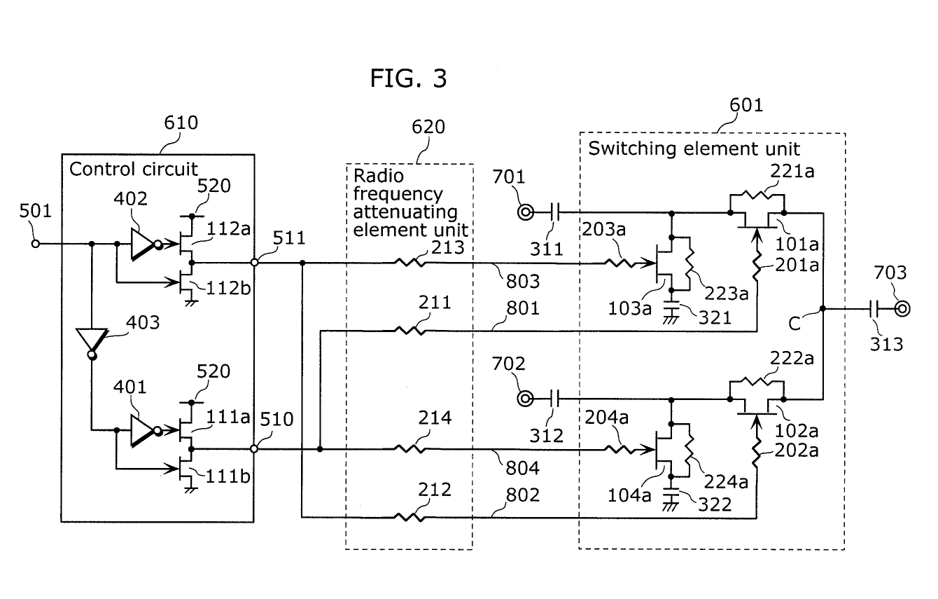

Next, a radio frequency switching circuit according to a second embodiment of the present invention is described with reference to FIG. 3. FIG. 3 is a diagram showing an equivalent circuit of the radio frequency switching circuit according to the second embodiment of the present invention.

The switching circuit of the second embodiment shown in FIG. 3 has a basic configuration identical to that of the radio frequency switching circuit according to the first embodiment shown in FIG. 1; however the radio frequency switching circuit according to the second embodiment of the present invention differs from the radio frequency switching circuit according to the first embodiment of the present invention in that a radio frequency attenuating element unit 620 is arranged between the switching element unit 601 and the control circuit 610. Note that the same numerical references are given to the same constituent elements as those in the first embodiment, and the descriptions thereof are simplified or omitted.

As shown in FIG. 3, the radio frequency attenuating element unit 620 in the radio frequency switching circuit according to the second embodiment of the present invention includes four radio frequency attenuating elements that are attenuating resistive elements 211, 212, 213, and 214. One terminal (output terminal) of the attenuating resistive element 211 is connected to the second terminal of the biasing resistive element 201a and one terminal (output terminal) of the attenuating resistive element 214 is connected to the second terminal of the biasing resistive element 204a. The other terminals (input terminals) of the attenuating resistive elements 211 and 214 are connected to a first control signal output terminal 510. Similarly, one terminal (output terminal) of the attenuating resistive element 212 is connected to the second terminal of the biasing resistive element 202a and one terminal (output terminal) of the attenuating resistive element 213 is connected to the second terminal of the biasing resistive element 203a. The other terminals (input terminals) of the attenuating resistive elements 212 and 213 are connected to a second control signal output terminal 511.

In the radio frequency switching circuit according to the second embodiment of the present invention, the attenuating resistances of the attenuating resistive elements 211 to 214 prevent radio frequency signals coupled to the control signal lines 801 to 804 from being input to the control circuit 610. Accordingly, the radio frequency switching circuit according to the second embodiment of the present invention can operate the control circuit 610 more stably even at the time of large electric power signal input, compared to the radio frequency switching circuit according to the first embodiment.

In the second embodiment, it is set such that the resistance value Rb1a of the biasing resistive element 201a is 50 kΩ, the resistance value Rd1 of the attenuating resistive element 211 is 10 kΩ, the resistance value Rb4a of the biasing resistive element 204a is 100 kΩ, and the resistance value Rd4 of the attenuating resistive element 214 is 50 kΩ. More specifically, the relationship is Rd1<Rd4=Rb1a<Rb4a, and Rb1a+Rd1<Rb4a+Rd4. Note that the gate width W1a and the gate capacitance C1a of the transmission FET 101a and the gate width W4a and the gate capacitance C4a of the shunt FET 104a are the same as those of the first embodiment; and thus, the relationship is W1a>W4a, and C1a>C4a. With those settings, the time constant determined by the gate capacitance C4a of the shunt FET 104a, the resistance value Rb4a of the biasing resistive element 204a, and the resistance value Rd4 of the attenuating resistive element 214 can be made greater than the time constant determined by the gate capacitance C1a of the transmission FET 101a, the resistance value Rb1a of the biasing resistive element 201a and the resistance value Rd1 of the attenuating resistive element. Therefore, time at which the shunt FET 104a is switched to an on state can be delayed and the increase of the drain-to-source potential of the transmission FET 101a can be delayed.

As a result, time at which the potential at point C that is a common potential of the switching element unit 601 increases can be delayed, and the absolute value of the voltage variation can also be decreased. Therefore, similar to the first embodiment, time period required for switching the transmission FET 101a to an on state can be reduced.

Similarly, time period required for switching the reception FET 102a to an on state can be reduced for the reception FET 102a, the shunt FET 103a, the biasing resistive elements 202a and 203, and the attenuating resistive elements 212 and 213 as well.

Here, in the case where a radio frequency signal is input from the transmission terminal 701 and transmitted to the antenna terminal 703, switching time in the radio frequency switching circuit according to the second embodiment of the present invention where the resistance values Rb1a and Rb2a of the biasing resistive elements 201a and 202a are 50 kΩ and the resistance values Rb3a and Rb4a of the biasing resistive elements 203a and 204a are 100 kΩ can be reduced significantly compared to the switching time in the conventional switching circuit where the resistance values of the biasing resistive elements 201a to 204a are all the same.

As described, in the second embodiment, of the two FETs that are simultaneously switched to an on state, switching time can be reduced for a control signal path which has a relatively larger gate width of the FET, that is a control signal path which has a relatively larger gate capacitance by relatively decreasing the sum of the biasing resistance value of the biasing resistive element connected to the gate terminal of the FET and the resistance value of the attenuating resistive element to which the biasing resistive element is connected, compared to the case where the biasing resistive elements having a same biasing resistance value and the attenuating resistive elements having a same resistance value are used.

In the present embodiment, the transmission FET 101a and the reception FET 102b, which are transfer path FETs, have gate widths larger than those of the shunt FETs 103a and 104a which are shunt path FETs. Therefore, the sum of the resistance values of the biasing resistive elements connected to the transmission FET 101a and the reception FET 102b and the resistance values of the attenuating resistive elements connected to those biasing resistive elements is set to be smaller than the sum of the resistance values of the biasing resistive elements connected to the shunt FETs 103a and 104a and the resistance values of the attenuating resistive elements connected to those biasing resistive elements. This allows reduction of switching time.

According to the second embodiment, switching time can be reduced by making time constant of the circuit including the gate capacitance of the FET, the biasing resistive element and the attenuating resistive element identical to the time constant of other path which is simultaneously switched to an on state. In addition, by arranging the attenuating resistive element between the switching element and the control circuit, it is also possible to stabilize the control circuit.

Similar to the first embodiment, W1>W2, C1>C2, and Rb1+Rd1<Rb2+Rd2 are satisfied where the transmission FET 101a is a first switching element, the shunt FET 104a is a second switching element, the biasing resistive element 201a connected to the transmission FET 101a is a first biasing resistive element, the biasing resistive element 204a connected to the shunt FET 104a is a second biasing resistive element, the gate width W1a and the gate capacitance C1a of the transmission FET 101a that is the first switching element are respectively W1 and C1, the gate width W4a and the gate capacitance C1a of the shunt FET 104a that is the second switching element are respectively W2 and C2, the resistance value Rb1a of the biasing resistive element 201a connected to the transmission FET 101a that is the first switching element is Rb1, the resistance value Rb4a of the biasing resistive element 204a connected to the shunt FET 104a that is the second switching element is Rb2, the attenuating resistive element 211 connected to the biasing resistive element 201a that is a first biasing resistive element is a first resistive element, the resistance value of the first resistive element is Rd1, the attenuating resistive element 214 connected to the biasing resistive element 204a that is a second biasing resistive element is a second resistive element, and the resistance value of the second resistive element is Rd2.

Further, Rb1+Rd1<Rb3+Rd3 is satisfied where the reception FET 102a is a third switching element, the biasing resistive element 202a connected to the reception FET 102a is a third biasing resistive element, the attenuating resistive element 212 connected to the biasing resistive element 202a that is the third biasing resistive element is a third resistive element, the gate width W2a and the gate capacitance C2a of the reception FET 102a that is the third switching element are respectively W3 and C3, the resistance value Rb2a of the biasing resistive element 202a connected the reception FET 102a that is the third switching element is Rb3, the resistance value Rd2 of the attenuating resistive element 212 that is the third resistive element is Rd3.

Note that it is set such that Rp(TX)+Rd(TX)<Rp(RX)+Rd(RX), or Rp(TX)+Rd(TX)<Rp(SNT)+Rd(SNT) is satisfied, where the resistance value Rb1 of the first biasing resistive element for the transmitting path FET is Rp(TX), the resistance value Rb2 of the second biasing resistive element for the shunt path FET is Rp(SNT), the resistance value Rb3 of the third biasing resistive element for the receiving path FET is Rp(RX), the resistance value Rd1 of the first resistive element is Rd(TX), the resistance value Rd2 of the second resistive element is Rd(SNT) and the resistive value Rd3 of the third resistive element is Rd(RX).

### Third Embodiment

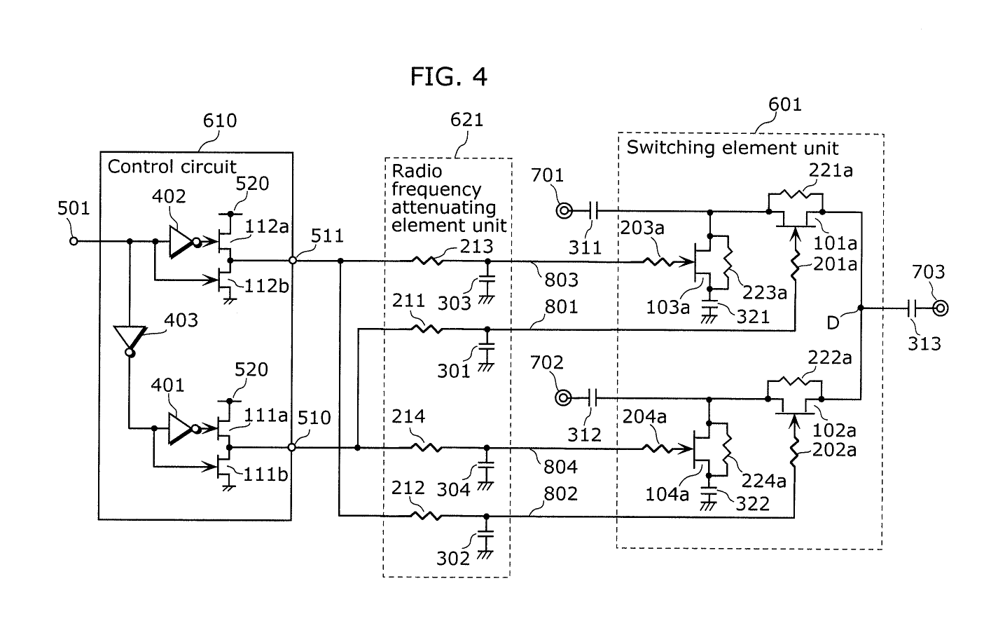

Next, a radio frequency switching circuit according to a third embodiment of the present invention is described with reference to FIG. 4. FIG. 4 is a diagram showing an equivalent circuit of the radio frequency switching circuit according to the third embodiment of the present invention.

The switching circuit according to the third embodiment shown in FIG. 4 has a basic configuration identical to that of the radio frequency switching circuit according to the second embodiment shown in FIG. 3; however, the radio frequency switching circuit according to the third embodiment of the present invention differs from the radio frequency switching circuit according to the first embodiment of the present invention in that shunt capacitors 301 to 304 are connected as a radio frequency attenuating element unit. Note that the same numerical references are given to the same constituent elements as those in the second embodiment, and the descriptions thereof are simplified or omitted.

As shown in FIG. 4, the radio frequency attenuating element unit 621 in the radio frequency switching circuit according to the third embodiment of the present invention includes four attenuating resistive elements 211, 212, 213, and 214, and shunt capacitors 301 to 304. One terminal of each of the shunt capacitors 301, 302, 303, and 304 are respectively connected to one terminal (output terminal) of each of the attenuating resistive elements 211, 212, 213, and 214. Further, the other terminals of the shunt capacitors 301, 302, 303, and 304 are grounded.

The radio frequency switching circuit according to the third embodiment of the present invention can further improve radio frequency attenuation properties and obtain more stable control circuit operation by adding the shunt capacitors 301 to 304.

Note that it is desirable that the capacitance values of the shunt capacitors 301 to 304 are set to be values which do not influence time constant of the circuit. In the third embodiment, influences on time constant can be suppressed by setting the capacitance values of the shunt capacitors 301 to 304 to be 0.5 pF, and control circuit can be stabilized without degradation of switching time.

As described, by arranging, between the switching element unit 601 and the control circuit 610, the radio frequency attenuating element unit 621 including the attenuating resistive elements and the shunt capacitors, it is possible to further stabilize the control circuit.

Note that it is not necessary that the capacitance values of the shunt capacitors 301 to 304 are the same. The path which has greater coupling of radio frequency signals can enhance the effect by increasing the capacitance values.

### Fourth Embodiment

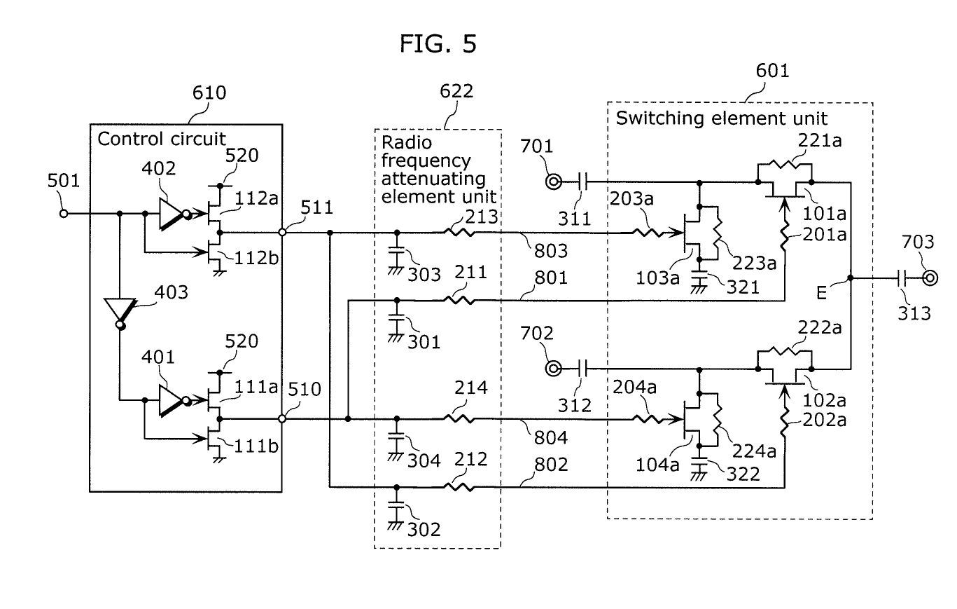

Next, a radio frequency switching circuit according to a fourth embodiment of the present invention is described with reference to FIG. 5. FIG. 5 is a diagram showing an equivalent circuit of the radio frequency switching circuit according to the fourth embodiment of the present invention.

The switching circuit according to the fourth embodiment shown in FIG. 5 has a basic configuration identical to that of the radio frequency switching circuit according to the third embodiment shown in FIG. 4; however, the radio frequency switching circuit according to the fourth embodiment of the present invention differs from the radio frequency switching circuit according to the third embodiment of the present invention in that the shunt capacitors 301 to 304 are connected to the input terminals of the attenuating resistive elements 211 to 214. Note that the same numerical references are given to the same constituent elements as those in the third embodiment, and the descriptions thereof are simplified or omitted.

As shown in FIG. 5, the radio frequency attenuating element unit 622 in the radio frequency switching circuit according to the fourth embodiment of the present invention includes the attenuating resistive elements 211, 212, 213, and 214, and the shunt capacitors 301 to 304. One terminal of each of the shunt capacitors 301, 302, 303, and 304 are respectively connected to the other terminal (input terminal) of each of the attenuating resistive elements 211, 212, 213, and 214. Further, the other terminals of the shunt capacitors 301, 302, 303, and 304 are grounded.

The radio frequency switching circuit according to the fourth embodiment of the present invention can eliminate the influences of time constant of the biasing resistive elements 201a to 204a and the shunt capacitors 301 to 304 by connecting the shunt capacitors 301 to 304 to the input terminal side of the radio frequency attenuating element unit 622. This allows stable operation of the control circuit 610 and reduction of switching time at the same time.

Note that in the fourth embodiment, the capacitance values of the shunt capacitors 301 to 304 are set to be 1 pF. This allows elimination of influences on time constant of the FETs 101a to 104a.

In the fourth embodiment, similar to the second embodiment, it is set such that the resistance value Rb1a of the biasing resistive element 201a is 50 kΩ, the resistance value Rd1 of the attenuating resistive element 211 is 10 kΩ, the resistance value Rb4a of the biasing resistive element 204a is 100 kΩ, and the resistance value Rd4 of the attenuating resistive element 214 is 50 kΩ. More specifically, the relationship is Rd1<Rd4=Rb1a<Rb4a, and Rb1a+Rd1<Rb4a+Rd4. Note that the gate width W1a and the gate capacitance C1a of the transmission FET 101a and the gate width W4a and the gate capacitance C4a of the shunt FET 104a are also set similarly to the second embodiment; and thus, the relationship is W1a>W4a, and C1a>C4a. With those settings, the time constant determined by the gate capacitance C4a of the shunt FET 104a, the resistance value Rb4a of the biasing resistive element 204a and the resistance value Rd4 of the attenuating resistive element 214 can be made greater than the time constant determined by the gate capacitance C1a of the transmission FET 101a, the resistance value Rb1a of the biasing resistive element 201a and the resistance value Rd1 of the attenuating resistive element. Therefore, time at which the shunt FET 104a is switched to an on state can be delayed and the increase of the drain-to-source potential of the transmission FET 101a can be delayed.

As a result, time at which the potential at point E that is a common potential of the switching element unit 601 increases can be delayed, and the absolute value of the voltage variation can also be decreased. Therefore, similar to the second embodiment, time period required for switching the transmission FET 101a to an on state can be reduced.

Similarly, time period required for switching the reception FET 102a to an on state can be reduced for the reception FET 102a, the shunt FET 103a, the biasing resistive elements 202a and 203, and the attenuating resistive elements 212 and 213 as well.

Here, in the case where a radio frequency signal is input from the transmission terminal 701 and transmitted to the antenna terminal 703, switching time in the radio frequency switching circuit according to the fourth embodiment of the present invention where the resistance values Rb1a and Rb2a of the biasing resistive elements 201a and 202a are 50 kΩ and the resistance values Rb3a and Rb4a of the biasing resistive elements 203a and 204a are 100 kΩ can be reduced significantly compared to the switching time in the conventional switching circuit where the resistance values of the biasing resistive elements 201a to 204a are all the same.

As described, in the fourth embodiment, of the two FETs that are simultaneously switched to an on state, switching time can be reduced for a control signal path which has a relatively larger gate width of the FET, that is a control signal path which has a relatively larger gate capacitance by relatively decreasing the sum of the biasing resistance value of the biasing resistive element connected to the gate terminal of the FET and the resistance value of the attenuating resistive element to which the biasing resistive element is connected, compared to the case where the biasing resistive elements having a same biasing resistance value and the attenuating resistive elements having a same resistance value are used.

According to the fourth embodiment, it is possible not only to further stabilize the control circuit, but also to reduce switching time by arranging, between the switching element unit 601 and the control circuit 610, the radio frequency attenuating element unit 620 including attenuating resistances and shunt capacitors.

### Fifth Embodiment

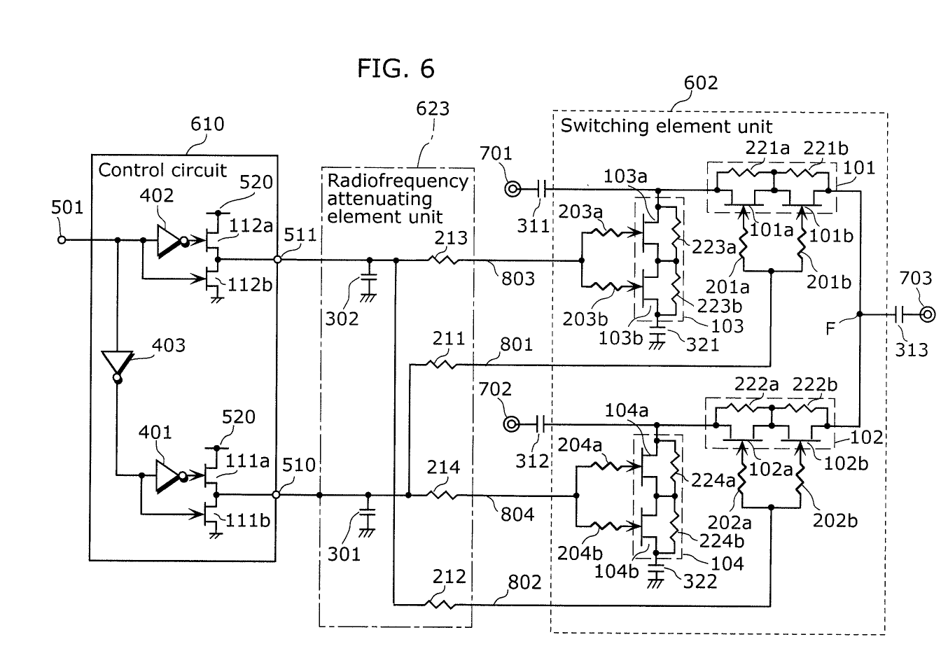

Next, a radio frequency switching circuit according to a fifth embodiment of the present invention is described with reference to FIG. 6. FIG. 6 is a diagram showing an equivalent circuit of the radio frequency switching circuit according to the fifth embodiment of the present invention.

The switching circuit according to the fifth embodiment shown in FIG. 6 has a basic configuration identical to that of the radio frequency switching circuit according to the first embodiment shown in FIG. 1; however, the radio frequency switching circuit according to the fifth embodiment of the present invention differs from the radio frequency switching circuit according to the first embodiment of the present invention in that a switch unit in which FETs are connected in series is used as a switching element unit 602, and that a radio frequency attenuating element unit 623 is used. Note that the same numerical references are given to the same constituent elements as those in the other embodiments, and the descriptions thereof are simplified or omitted.

As shown in FIG. 6, the switching element unit 602 in the radio frequency switching circuit according to the fifth embodiment of the present invention includes, as a switch unit, a transmission FET unit 101, a reception FET unit 102, and shunt FET units 103 and 104.

The transmission FET unit 101 includes two transmission FETs 101a and 101b that are connected in series and each having an input terminal, an output terminal and a gate terminal. A resistive element 221a is connected between the input terminal and the output terminal of the transmission FET 101a. Similarly, a resistive element 221b is connected between the input terminal and output terminal of the transmission FET 101b. The gate terminals of the transmission FET 101a and 101b are respectively connected to the first terminals of the two biasing resistive elements 201a and 201b. Further, the second terminals of the biasing resistive elements 201a and 201b are connected to the attenuating resistive element 211.

Similarly, the reception FET unit 102 includes two reception FETs 102a and 102b that are connected in series and each having an input terminal, an output terminal and a gate terminal. A resistive element 222a is connected between the input terminal and the output terminal of the reception FET 102a. Similarly, a resistive element 222b is connected between the input terminal and output terminal of the reception FET 102b. The gate terminals of the reception FET 102a and 102b are respectively connected to the first terminals of the two biasing resistive elements 202a and 202b. Further, the second terminals of the biasing resistive elements 202a and 202b are connected to the attenuating resistive element 212.

Similarly, the shunt FET unit 103 includes two shunt FETs 103a and 103b that are connected in series and each having an input terminal, an output terminal and a gate terminal. The shunt FET unit 104 also includes two shunt FETs 104a and 104b that are connected in series. The resistive element 223a is connected between the input terminal and the output terminal of the shunt FET 103a, and the resistive element 224a is connected between the input terminal and the output terminal of the shut FET 104a. The resistive elements 223b and 224b are respectively connected between the input terminals and the output terminals of the shunt FETs 103b and 104b. The gate terminals of the shunt FETs 103a, 103b, 104a, and 104b are respectively connected to the first terminals of the biasing resistive elements 203a, 203b, 204a and 204b. Further, the second terminals of the biasing resistive elements 203a and 203b are connected to the attenuating resistive element 213, and the second terminals of the biasing resistive elements 204a and 204b are connected to the attenuating resistive element 214.

The radio frequency attenuating element unit 623 according to the present embodiment includes the attenuating resistive elements 211, 212, 213, and 214, and shunt capacitors 301 and 302. One terminal of the shunt capacitor 301 is connected to the other terminals (input terminal) of the attenuating resistive elements 211 and 214. One terminal of the shunt capacitor 302 is connected to the other terminals (input terminal) of the attenuating resistive elements 212 and 213. Further, the other terminals of the shunt capacitors 301 and 302 are grounded.

Since the radio frequency switching circuit according to the fifth embodiment has a configuration in which the switch unit in the switching element unit 602 includes FETs that are connected in series, it is possible to divide voltage of the input radio frequency signal. Accordingly, even when a larger electric power signal is input, it is possible to obtain distortion properties as good as the distortion properties at the time of a smaller electric power signal is input.

Further, in the fifth embodiment, similar to the shunt capacitors 301 to 304 in the fourth embodiment, the shunt capacitor 301 at the connection portion of the control signal lines 801 and 804 and the shunt capacitor 302 at the connection portion of the control signal lines 802 and 803 are respectively connected to the input terminal sides of the frequency attenuating element unit 623. This allows elimination of influences of time constant of the biasing resistive elements 201a to 204a and the shunt capacitors 301 and 302.

Further, in the fifth embodiment, it is set that the resistive values Rb1a and Rb1b of the biasing resistive elements 201a and 201b are 50 kΩ, the resistance value Rd1 of the attenuating resistive element 211 is 10 kΩ, the resistance values of the biasing resistive elements 204a and 204b are 100 kΩ, and the resistance value Rd4 of the attenuating resistive element 214 is 50 kΩ. Here, the parallel resistance value Rp1 of the biasing resistive elements 201a and 201b and the parallel resistance value Rp4 of the biasing resistive elements 204a and 204b have a relationship of Rp1<Rp4. Further, they also have a relationship of Rp1+Rd1<Rp4+Rd4.

Further, the gate capacitances C1a, C1b, C4a, and C4b are set such that where the gate widths of the transmission FET 101a and 101b are respectively W1a and W1b, the gate capacitances of the transmission FET 101a and 101b are respectively C1a and C1b, and the gate widths of the shunt FET 104a and 104b are respectively W4a and W4b, the sum Ct1 of the gate capacitances of the two transmission FET 101a and 101b and the sum Ct4 of the gate capacitances of the two shunt FETs 104a and 104b have a relationship of Ct1>Ct4.

Further, the gate widths W1a, W1b, W4a, and W4b are set such that the sum Wt1 of the gate widths of the two transmission FET 101a and 101b and the sum Wt4 of the gate widths of the two shunt FETs 104a and 104b have a relationship of Wt1>Wt4.

With such settings, the time constant determined by the sum Ct4 of the gate capacitances of the two shunt FETs 104a and 104b, the parallel resistance value Rp4 of the biasing resistive elements 204a and 204b, and the resistance value Rd14 of the attenuating resistive element 214 can be made greater than the time constant determined by the sum Ct1 of the gate capacitances of the two transmission FETs 101a and 101b, the parallel resistance value Rp1 of the biasing resistive elements 201a and 201b, and the resistance value Rd1 of the attenuating resistive element 211. Therefore, time at which the shunt FETs 104a and 104b are switched to an on state can be delayed and the increase of the drain-to-source potential of the transmission FETs 101a and 101b can be delayed.

As a result, time at which the potential at point F that is a common potential of the switching element unit 602 increases can be delayed, and the absolute value of the voltage variation can also be decreased. Therefore, similar to the second embodiment, time period required for switching the transmission FETs 101a and 101b to an on state can be reduced.

Similarly, time period required for switching the reception FETs 102a and 102b to an on state can be reduced for the reception FETs 102a and 102b, the shunt FETs 103a and 103b, the biasing resistive elements 202a, 202b, 203a and 203, and the attenuating resistive elements 212 and 213 as well.

Here, in the case where a radio frequency signal is input from the transmission terminal 701 and transmitted to the antenna terminal 703, switching time in the radio frequency switching circuit according to the fifth embodiment of the present invention in the case where the resistance values of the biasing resistive elements 201a, 201b, 202a and 202b are 50 kΩ and the resistance values of the biasing resistive elements 203a, 203b, 204a and 204b are 100 kΩ can be reduced significantly compared to the switching time in the conventional switching circuit in the case where the resistance values of the biasing resistive elements 201a, 201b, 202a, 202b, 203a, 203b, 204a, and 204b are all the same.

As described, in the fifth embodiment, even in the case where a single switch unit includes plural FETs, of the two switch units that are simultaneously switched to an on state, switching time can be reduced by increasing the sum of the parallel resistance value of the biasing resistive elements that are connected to the gate terminal of each FET of the switch unit having a relatively smaller sum of the gate widths and the resistance value of the attenuating resistive element, compared to the sum of the parallel resistance value of the biasing resistive elements that are connected to the gate terminal of each FET of the switch unit having a relatively larger sum of the gate widths and the resistance value of the attenuating resistive element.

### Sixth Embodiment

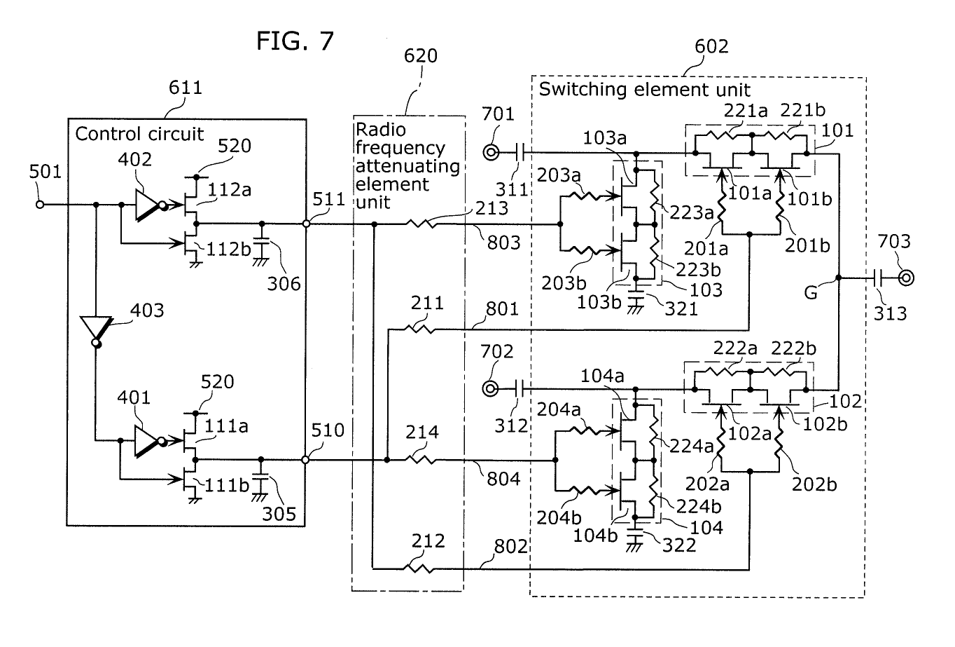

Next, a radio frequency switching circuit according to a sixth embodiment of the present invention is described with reference to FIG. 7. FIG. 7 is a diagram showing an equivalent circuit of the radio frequency switching circuit according to the sixth embodiment of the present invention.

The switching circuit according to the sixth embodiment shown in FIG. 7 has a basic configuration identical to that of the radio frequency switching circuit according to the fifth embodiment shown in FIG. 6. The deference is that the capacitor connected between the input terminals of the radio frequency attenuating element unit and ground in the radio frequency switching circuit of the fifth embodiment are arranged between the control signal output terminal of the control circuit and the ground in the radio frequency switching circuit according to the sixth embodiment of the present invention. Note that the same numerical references are given to the same constituent elements as those in the other embodiments, and the descriptions thereof are simplified or omitted.

As shown in FIG. 7, the control circuit 611 in the radio frequency switching circuit according to the sixth embodiment of the present invention includes capacitors 305 and 306 that are added compared to the control circuit 610 according to the fifth embodiment.

Here, one terminal of the capacitor 305 is connected to a connection terminal of the buffer FET 111a and the buffer FET 111b, and to the first control signal output terminal 510. Further, the other terminal of the capacitor 305 is grounded by, for example, being connected to a ground electrode. This makes the other terminal of the capacitor 305 a ground potential.

Similarly, one terminal of the capacitor 306 is connected to a connection terminal of the buffer FET 112a and the buffer FET 112b, and to the second control signal output terminal 511. Further, the other terminal of the capacitor 306 is grounded by, for example, being connected to a ground electrode. This makes the other terminal of the capacitor 306 a ground potential.

Note that the radio frequency attenuating element unit 620 has a configuration identical to that of the radio frequency attenuating element unit 620 in the second embodiment of the present invention; and thus description thereof is omitted.

As described, in the radio frequency switching circuit according to the sixth embodiment of the present invention, the first control signal output terminal 510 and the second control signal output terminal 511 are directly connected to the capacitors 305 and 306, respectively. As a result, radio frequency signals coupled by the control signal lines 801 to 804 can be effectively led to the ground electrodes connected to the capacitors 305 and 306, which allows more stable operation of the control circuit.

Note that as described in the first to fifth embodiments, it is not necessary that the time constants of paths that are simultaneously switched to an on state are completely identical. It is also possible to obtain sufficient advantageous effect by only making the resistance value or separate resistance value of the biasing resistive element of the FET on the path having a relatively smaller gate width approximately twice of the resistance value of the biasing resistive element or the resistance value of the attenuating resistive element of the FET on the path having a relatively larger gate width. Therefore, it is reasonable to select the resistance value of the biasing element, resistance value of the attenuating resistive element, and the capacitance value of the shunt capacitor according to required switching time.

Further, by integrating, on a semiconductor substrate, the radio frequency switching circuit obtained by each embodiment described above, it is possible to achieve a semiconductor device in which the switching operation of the radio frequency circuit is stabilized and switching time is reduced.

The radio frequency switching circuit according to the present invention has been described based on the first to sixth embodiments; however, the radio frequency switching circuit according to the present invention is not limited to those embodiments.

For example, in the above embodiments, N-type FET is used as FET, but the present invention is not limited to this. Further, the FET in each embodiment above has a drain terminal as an input terminal and a source terminal as an output terminal; however, the present invention is not limited to this. For example, such a FET that has a source terminal as an input terminal and a drain terminal as an output terminal is also possible.

Further, in the above embodiments, the control circuit 610 includes a single control signal input terminal, but may also include plural control signal input terminals.

Further, in the above embodiments, the control circuit 610 includes two control signal output terminals, but may also include more than two. The number of the control signal output terminals may be set appropriately according to the number of the FETs to be controlled.

Further in the fifth and sixth embodiments, the switch unit includes two FETs; however, two or more FETs may be connected in series.

Further, the formulas described in the first to fourth embodiments can be applied in the fifth and sixth embodiments as well. In this case, the resistance values Rb1, Rb2, and Rb3 of the biasing resistive elements in the first to fourth embodiments can be considered as parallel resistance values of the biasing resistive elements connected to the FETs in each switch unit in the fifth and sixth embodiments.

Although only some exemplary embodiments of this invention have been described in detail above, those skilled in the art will readily appreciate that many modifications are possible in the exemplary embodiments without materially departing from the novel teachings and advantages of this invention. Accordingly, all such modifications are intended to be included within the scope of this invention.

### INDUSTRIAL APPLICABILITY

The present invention is useful for stable operation of the radio frequency switching circuit and for reduction of switching time.

What is claimed is:

1. A radio frequency switching circuit comprising:
a first switching element which includes a control terminal and switches between on and off states according to a control signal being input to said control terminal;
a second switching element which includes a control terminal and switches between on and off states according to the control signal being input to said control terminal;
a first biasing resistive element which includes one terminal connected to said control terminal of said first switching element;
a second biasing resistive element which includes one terminal connected to said control terminal of said second switching element; and
a control circuit which includes a control signal output terminal connected to the other terminal of said first biasing resistive element and the other terminal of said second biasing resistive element, and controls said first switching element and said second switching element according to the control signal being output from said control signal output terminal,
wherein, C1>C2 and Rb1<Rb2 are satisfied (i) where a capacitance of said control terminal of said first switching element is C1, and a capacitance of said control terminal of said second switching element is C2, and (ii) where a resistance value of said first biasing resistive element is Rb1, and a resistance value of said second biasing resistive element is Rb2.

2. The radio frequency switching circuit according to claim 1,
wherein each of said first switching element and said second switching element is formed of a field effect transistor, and said control terminal of each of said first switching element and said second switching element is a gate terminal, and
W1>W2 is satisfied, where a gate width of said field effect transistor forming said first switching element is W1, and a gate width of said field effect transistor forming said second switching element is W2.

3. The radio frequency switching circuit according to claim 1,
wherein both of said first switching element and said second switching element are switched to an on state or an off state according to the control signal.

4. The radio frequency switching circuit according to claim 1,
wherein C1 is a capacitance between said control terminal of said first switching element and ground, and
C2 is a capacitance between said control terminal of said second switching element and ground.

5. The radio frequency switching circuit according to claim 1, comprising:
a third switching element which includes a control terminal and switches between on and off states according to the control signal being input to said control terminal;
a fourth switching element which includes a control terminal and switches between on and off states according to the control signal being input to said control terminal;
a third biasing resistive element which includes one terminal connected to said control terminal of said third switching element; and
a fourth biasing resistive element which includes one terminal connected to said control terminal of said fourth switching element,
wherein the other terminal of said third biasing resistive element and the other terminal of said fourth biasing resistive element are connected to said control signal output terminal,
said third switching element is connected in series with said first switching element, and said first switching element and said third switching element form a first switch unit,
said fourth switching element is connected in series with said second switching element, and said second switching element and said fourth switching element form a second switch unit, and
Ct1>Ct2 and Rp1<Rp2 are satisfied, (i) where a sum of the capacitance of said control terminal of said first switching element and a capacitance of said control terminal of said third switching element is Ct1, said first switching element and said third switching element forming said first switch unit, and a sum of the capacitance of said control terminal of said second switching element and a capacitance of said control terminal of said fourth switching element is Ct2, said second switching element and said fourth switching element forming said second switch unit, and (ii) where a parallel resistance value of said first biasing resistive element and said third biasing resistive element that are respectively connected to said first switching element and said third switching element is Rp1, said first switching element and said third switching element forming said first switch unit, and a parallel resistance value of said second biasing resistive element and said fourth biasing resistive element that are respectively connected to said second switching element and said fourth switching element is Rp2, said second switching element and said fourth switching element forming said second switch unit.

6. The radio frequency switching circuit according to claim 5,
wherein each of said first switching element, said second switching element, said third switching element, and said fourth switching element is formed of a field effect transistor, and said control terminal of each of said first switching element, said second switching element, said third switching element, and said fourth switching element is a gate terminal, and
Wt1>Wt2 is satisfied where a sum of a gate width of said field effect transistor of said first switching element and a gate width of said field effect transistor of said third switching element is Wt1, said first switching element and said third switching element forming said first switch unit, and where a sum of a gate width of said field effect transistor of said second switching element and a gate width of said field effect transistor of said fourth switching element is Wt2, said second switching element and said fourth switching element forming said second switch unit.

7. The radio frequency switching circuit according to claim 5,
wherein all of said first switching element, said second switching element, said third switching element, and said fourth switching element are switched to an on state or an off state according to the control signal.

8. The radio frequency switching circuit according to claim 5,
wherein Ct1 is calculated based on a capacitance between said control terminal of said first switching element and ground and a capacitance between said control terminal of said third switching element and ground, and
Ct2 is calculated based on a capacitance between said control terminal of said second switching element and ground and a capacitance between said control terminal of said fourth switching element and ground.

9. A radio frequency switching circuit comprising:
a first switching element which includes a control terminal and switches between on and off states according to a control signal being input to said control terminal;
a second switching element which includes a control terminal and switches between on and off states according to the control signal being input to said control terminal;
a first biasing resistive element which includes one terminal connected to said control terminal of said first switching element;
a second biasing resistive element which includes one terminal connected to said control terminal of said second switching element;
a radio frequency attenuating element connected to at least one of the other terminal of said first biasing resistive element and the other terminal of said second biasing resistive element; and
a control circuit which includes a control signal output terminal connected to an input terminal of said radio frequency attenuating element and controls on and off states of said first switching element and said second switching element according to the control signal being output from said control signal output terminal.

10. The radio frequency switching circuit according to claim 9,
wherein said radio frequency attenuating element is formed of at least one resistive element.

11. The radio frequency switching circuit according to claim 10, further comprising
a capacitor which includes one terminal connected to an output terminal of said at least one resistive element forming said radio frequency attenuating element and the other terminal being grounded.

12. The radio frequency switching circuit according to claim 10, further comprising
a capacitor which includes one terminal connected to an input terminal of said at least one resistive element forming said radio frequency attenuating element and the other terminal being grounded.

13. The radio frequency switching circuit according to claim 10,
wherein said at least one resistive element forming said radio frequency attenuating element includes a plurality of resistive elements,
said plurality of resistive elements include:
a first resistive element connected to the other terminal of said first biasing resistive element; and
a second resistive element connected to the other terminal of said second biasing resistive element, and
a resistance value of said first resistive element is different from a resistance value of said second resistive element.

14. The radio frequency switching circuit according to claim 13,
wherein τ1>τ2 and Rd1<Rd2 are satisfied, (i) where a time constant of a load connected to an output terminal of said first resistive element is τ1 and a time constant of a load connected to an output terminal of said second resistive element is τ2, and (ii) where a resistance value of said first resistive element is Rd1 and a resistance value of said second resistive element is Rd2.

15. The radio frequency switching circuit according to claim 10,
wherein said at least one resistive element forming said radio frequency attenuating element includes a plurality of resistive elements,
said plurality of resistive elements include:
a first resistive element connected to the other terminal of said first biasing resistive element; and
a second resistive element connected to the other terminal of said second biasing resistive element,
each of said first switching element and said second switching element is formed of a field effect transistor,
said control terminal of each of said first switching element and said second switching element is a gate terminal, and
W1>W2, and Rb1+Rd1<Rb2+Rd2 are satisfied, (i) where a gate width of said field effect transistor forming said first switching element is W1, and a gate width of said field effect transistor forming said second switching element is W2, (ii) where a resistance value of said first biasing resistive element is Rb1, and a resistance value of said second biasing resistive element is Rb2, and (iii) where a resistance value of said first resistive element is Rd1, and a resistance value of said second resistive element is Rd2.

16. The radio frequency switching circuit according to claim 10, comprising:
a third switching element which includes a control terminal and switches between on and off states according to the control signal being input to said control terminal;
a fourth switching element which includes a control terminal and switches between on and off states according to the control signal being input to said control terminal;
a third biasing resistive element which includes one terminal connected to said control terminal of said third switching element; and
a fourth biasing resistive element which includes one terminal connected to said control terminal of said fourth switching element,
wherein the other terminal of said third biasing resistive element and the other terminal of said fourth biasing resistive element are connected to said control signal output terminal,
said third switching element is connected in series with said first switching element, and said first switching element and said third switching element form a first switch unit,
said fourth switching element is connected in series with said second switching element, and said second switching element and said fourth switching element form a second switch unit,
each of said first switching element, said second switching element, said third switching element, and said fourth switching element is formed of a field effect transistor, and said control terminal of each of said first switching element, said second switching element,
said third switching element, and said fourth switching element is a gate terminal,
said at least one resistive element forming said radio frequency attenuating element includes a plurality of resistive elements;
said plurality of resistive elements include:
a first resistive element connected to the other terminal of said first biasing resistive element; and
a second resistive element connected to the other terminal of said second biasing resistive element, and
Wt1>Wt2, and Rp1+Rd1<Rp2+Rd2 are satisfied, (i) where a sum of a gate width of said field effect transistor of said first switching element and a gate width of said field effect transistor of said third switching element is Wt1, said first switching element and said third switching element forming said first switch unit, and a sum of a gate width of said field effect transistor of said second switching element and a gate width of said field effect transistor of said fourth switching element is Wt2, said second switching element and said fourth switching element forming said second switch unit, (ii) where a parallel resistance value of said first biasing resistive element and said third biasing resistive element that are respectively connected to said first switching element and said third switching element is Rp1, said first switching element and said third switching element forming said first switch unit, and a parallel resistance value of said second biasing resistive element and said fourth biasing resistive element that are respectively connected to said second switching element and said fourth switching element is Rp2, said second switching element and said fourth switching element forming said second switch unit, and (iii) where a resistance value of said first resistive element is Rd1 and a resistance value of said second resistive element is Rd2.

17. A radio frequency switching circuit comprising:
a switching element unit including:
at least one transmission terminal;
at least one reception terminal;
at least one antenna terminal;
a transmission path switching element formed of at least one field effect transistor and positioned between said at least one transmission terminal and said at least one antenna terminal;
a reception path switching element formed of at least one field effect transistor and positioned between said at least one reception terminal and said at least one antenna terminal; and
a shunt path switching element formed of at least one field effect transistor and positioned between said at least one transmission terminal and ground, between said at least one reception terminal and the ground, or between said at least one antenna terminal and the ground,
a first biasing resistive element which includes one terminal connected to a control terminal of said transmission path switching element;
a second biasing resistive element which includes one terminal connected to a control terminal of said shunt path switching element;
a third biasing resistive element which includes one terminal connected to a control terminal of said reception path switching element;
a first resistive element connected to the other terminal of said first biasing resistive element;
a second resistive element connected to the other terminal of said second biasing resistive element;
a third resistive element connected to the other terminal of said third biasing resistive element; and
a control circuit which includes a control signal output terminal, and switches on and off states of said transmission path switching element, said reception path switching element, and said shunt path switching element according to a control signal being output from said control signal output terminal,
wherein Rp (TX)+Rd (TX)<Rp (RX)+Rd (RX), or Rp (TX)+Rd (TX)<Rp (SNT)+Rd (SNT) is satisfied, (i) where a parallel resistance value of said first biasing resistive element is Rp (TX), a parallel resistance value of said second biasing resistive element is Rp (SNT), and a parallel resistance value of said third biasing resistive element is Rp (RX), and (ii) where a resistance value of said first resistive element is Rd (TX), a resistance value of said second resistive element is Rd (SNT), and a resistance value of said third resistive element is Rd (RX).

18. The radio frequency switching circuit according to claim 1,
wherein said control circuit further includes a capacitor, said capacitor having one terminal connected to said control signal output terminal and the other terminal being grounded.

19. A semiconductor device which includes a semiconductor substrate on which said radio frequency switching circuit according to claim 1 is integrated.

20. A semiconductor device which includes a semiconductor substrate on which said radio frequency switching circuit according to claim 9 is integrated.
